(19) United States
(12) Patent Application Publication
(10) Pub. No.: US 2017/0332514 A1
(43) Pub. Date: Nov. 16, 2017

(54) COOLING SYSTEM AND COOLING METHOD FOR ELECTRONIC EQUIPMENT

(71) Applicant: ExaScaler Inc., Tokyo (JP)

(72) Inventor: Motoaki SAITO, Tokyo (JP)

(21) Appl. No.: 15/526,477

(22) PCT Filed: Nov. 14, 2014
(86) PCT No.: PCT/JP2014/080278

§ 371 Date: May 12, 2017

(51) Int. Cl. H05K 7/20; F28D 15/02; H01L 23/427; G06F 1/20; F25D 9/00

(52) U.S. Cl. CPC H05K 7/20236; H01L 23/427; F28D 15/02; G06F 1/20; F25D 9/00; H01L 2924/0002; H05K 7/20254; H05K 7/20281

(57) ABSTRACT

There are provided a cooling system and a cooling method that are simple and efficient and improve cooling performances for an electronic device. A cooling system (10) includes a cooling bath (12). In the open space of the cooling bath (12), a second coolant (13) with a boiling point (T₂) is contained. In the open space of the cooling bath (12), an electronic device (100) is housed. The electronic device (100) is mounted with a processor (110) as a heat generating component on a board (120). The electronic device (100) is immersed in the second coolant 13. A boiling cooling device (200) is a cooling device thermally connected to the processor (110), and encloses a first coolant 11 with a boiling point (T₁) (where T₂>T₁).

### TECHNICAL FIELD

The present invention relates to a cooling system for an electronic device, and more specifically to a cooling system and a cooling method for an electronic device, which efficiently cool an electronic device that is requested to operate in ultra-high performance mode or to operate stably on supercomputers, at data centers, or the like, and generates a large quantity of heat.

### BACKGROUND ART

One of the biggest problems to determine the limits of performances of today's supercomputers is power consumption. The importance of studies on the energy efficiency of supercomputers is already widely recognized. In other words, floating point operations per second per watt (FLOPS/Watt) is one indicator to evaluate supercomputers. In data centers, it is estimated that electric power is used for cooling by about 45% of the power consumption in the entire data centers. There is an increasing demand to decrease power consumption by improving cooling efficiency.

Conventionally, air cooling systems and liquid cooling systems are used for cooling supercomputers and data centers. The liquid cooling system uses a liquid excellent in heat transfer performance much better than the heat transfer performance of air. Thus, the liquid cooling system is widely considered to be excellent in cooling efficiency. For example, TSUBAME-KFC, which was constructed by Tokyo Institute of Technology, achieved 4.50 GFLOPS/Watt with a liquid immersion cooling system using synthetic oil. TSUBAME-KFC won the top place in the Supercomputer Green500 List announced in November 2013 and June 2014. However, synthetic oil of high viscosity is used for its coolant. Hence, this causes a difficulty of completely removing the oil attached to an electronic device after the electronic device is taken out of an oil immersion rack. This leads to a problem in that the maintenance of electronic devices is extremely difficult (specifically, adjustment, inspection, repair, replacement, and addition, for example, and hereinafter, the same meaning is applied). Moreover, a problem is reported that the synthetic oil for use corrodes a gasket and the other parts configuring the cooling system for a short time to cause leakage, resulting in a hindrance in operation.

On the other hand, a liquid immersion cooling system is proposed, which uses a fluorocarbon coolant, not synthetic oil that causes the problems described above. Specifically, the system is an example using a fluorocarbon coolant that is a hydrofluoroether (HFE) compound known as Novec 7100, Novec 7200, and Novec 7300, which are trade names of 3M Company. Novec is a trademark of 3M Company. Hereinafter, the same meaning is applied. See Patent Literatures 1 and 2, for example.

In order to locally cool a heat generating component, such as a CPU, which specifically generates a large quantity of heat, some examples of cooling devices are proposed, which use a boiling cooling system that transports and dissipates heat by vaporization and condensation of a coolant. One of the cooling devices is an example of a cooling module. The cooling module includes an evaporator connected to the heat generating surface of a processor and a condenser connected to an air-cooling fan or a water-cooling tube. The evaporator is connected to the condenser through two tubes for circulating a cooling medium using vapor-liquid equilibrium (NonPatent Literature 1). Another one is an example in which a special fluid channel wall is formed in the inside of a flat plate container, the flat plate container is filled with a coolant, the heat receiving region of the flat plate container is thermally connected to a heat generating component, the heat dissipation region of the flat plate container is connected to a heat dissipation unit, such as heat dissipating fins, and the heat dissipation region forms the passage of the coolant in the heat dissipation region (e.g. Patent Literature 3).

### CITATION LIST

### Patent Literature

Patent Literature 1: Japanese Unexamined Patent Application Publication No. 2013-187251

Patent Literature 2: Japanese Unexamined Patent Application Publication (Translation of PCT Application) No. 2012-527109

Patent Literature 3: Japanese Unexamined Patent Application Publication No. 2013-69740

NonPatent Literature 1: Research and Development Project for Green Network/System Technology, “Research and Development of Heat-Concentrating Cooling System Using Boiling Heat Transfer (from fiscal 2008 to 2012, five years)” pp. 8-9 and 11, Jul. 17, 2013 URL:http://www.nedo.go.jp/content/100532511.pdf

### SUMMARY OF INVENTION

### Technical Problem

Since the cooling system disclosed in Patent Literature 1 uses heat of vaporization (latent heat) for cooling an electronic device, a fluorocarbon coolant with a boiling point of 100° C. or less is used. The heat of an element mounted on the electronic device is removed by heat of vaporization (latent heat) when the coolant is evaporated by heat generated from the element, and hence the element is cooled. Hence, the fluorocarbon coolant locally boils on the surface of the element at a high temperature, and the bubbles sometimes form a heat insulation film. Thus, this causes a problem in that a high thermal conduction capability, which the coolant originally posses, is degraded. Electronic devices used on modern supercomputers and at data centers, for example, include a large number of components that have to be cooled, such as a graphics processing unit (GPU), high speed storage, chip set, network unit, bus switch unit, and solid state drive (SSD), other than a central processing unit (CPU). It is difficult to equally cool all of these components with different vaporization temperatures. Cooling efficiency becomes extremely poor in a component when the cooling medium on the surface of the component is not vaporized.

The cooling system disclosed in Patent Literature 2 adopts the configuration of a sealable module that contains one or more heat generating electronic components. Thus, this causes complexity of the overall mechanism for distributing a coolant to the individual sealable modules. Moreover, the entire electronic device is not allowed to be easily removed from the sealable module. Hence, there is a problem in that the maintenability of the electronic device is poor.

The cooling module proposed in Research and Development Project for Green Network/System Technology needs to separately provide two tubes connecting the evaporator on a processor to the condenser placed apart from the evaporator. Thus, the cooling module has a problem in that the configuration of the overall cooling module is increased in size and becomes complicated. Additionally, the presence of these tubes interferes with cooling electronic components around the processor, which have to rely on air cooling, and in secondary cooling using cooling fans or pipes, specifically in the case of using pipes, cooling efficiency remains poor because of the restrictions of flow rates in the pipes. Thus, the cooling module has a problem in that cooling performances for the overall electronic devices are restricted. On the other hand, the cooling device disclosed in Patent Literature 3 is advantageous because it can provide a small-sized boiling cooling device for local primary cooling. However, the cooling device has a problem in that cooling performances for the overall electronic device fail to be improved by the application of a previously existing secondary cooling technique of low cooling efficiency.

As described above, the previously existing liquid immersion cooling system has problems in that the overall mechanism for distributing the coolant through the sealable module is complicated and the maintenability of the electronic device is poor. The previously existing boiling cooling system has problems in that although the system is suited to locally cooling the electronic device, the overall mechanism is likely to be increased in size and complicated and cooling performances for the overall electronic device fail to be improved because the cooling efficiency of secondary cooling is poor.

Therefore, an object of the present invention is to provide a simple, efficient cooling system and a cooling method that solve the problems of the previously existing techniques and improve cooling performances for an electronic device.

### Solution to Problem

In order to solve the problems, an aspect of the present invention provides a cooling system that immerses an electronic device in a coolant for directly cooling the electronic device, the system including: a boiling cooling device thermally connected to at least one heat generating component of an electronic device, the boiling cooling device enclosing a first coolant with a boiling point T₁; and a cooling bath containing a second coolant with a boiling point T₂ higher than the boiling point T₁ of the first coolant, the boiling cooling device and the electronic device being immersed in the second coolant and directly cooled in the cooling bath.

In a preferred embodiment of the cooling system according to the present invention, a configuration may be provided, in which the boiling cooling device includes a closed container having a heat receiving part and a heat dissipating part and a heat dissipation member provided on the heat dissipating part, and when the boiling cooling device and the electronic device are immersed in the second coolant, the boiling cooling device is thermally connected to the heat generating component so that the heat dissipating part is located above the heat receiving part.

In a preferred embodiment of the cooling system according to the present invention, a configuration may be provided, in which the boiling point of the first coolant is a temperature of 100° C. or less, and the boiling point of the second coolant is a temperature of 150° C. or more.

In a preferred embodiment of the cooling system according to the present invention, a configuration may be provided, in which the first coolant contains a fluorocarbon compound as a main component.

In a preferred embodiment of the cooling system according to the present invention, a configuration may be provided, in which the second coolant contains a fully fluorinated compound as a main component.

In a preferred embodiment of the cooling system according to the present invention, a configuration may be provided, in which the electronic device has a plurality of heat generating components vertically disposed at different locations on a board, the boiling cooling device is thermally connected to the plurality of heat generating components individually, and a coolant with a boiling point higher than a boiling point of a coolant used for a cooling device located at a lower location on the board is used for a cooling device located vertically at an upper location on the board when the cooling devices are immersed in the second coolant.

In a preferred embodiment of the cooling system according to the present invention, a configuration may be provided, in which the cooling bath includes an inlet and an outlet for the second coolant, the outlet is joined to the inlet through a distribution path externally provided on the cooling bath, and in the distribution path, at least one pump that moves the second coolant and a heat exchanger that cools the second coolant are provided.

In a preferred embodiment of the cooling system according to the present invention, the system may be configured in which a header joined to the inlet and extending in a width direction of the cooling bath is disposed on a bottom part of the cooling bath so that the second coolant supplied from the inlet is discharged from a plurality of nozzles provided in an array on the header.

In a preferred embodiment of the cooling system according to the present invention, a configuration may be provided, in which the plurality of nozzles is formed of a plurality of nozzle groups provided being spaced at a predetermined gap in a longitudinal direction of the header, and the nozzle groups are configured of nozzles disposed so that discharge ports are radially distributed.

In a preferred embodiment of the cooling system according to the present invention, the plurality of nozzle groups may individually correspond to a plurality of the electronic devices immersed in the second coolant.

Moreover, another aspect of the present invention provides a cooling method for an electronic device including: thermally connecting a boiling cooling device enclosing a first coolant to at least one heat generating component of an electronic device; and immersing the boiling cooling device and the electronic device in a second coolant with a boiling point T₂ higher than a boiling point T₁ of the first coolant.

### Advantageous Effects of Invention

According to the cooling system of the present invention, the boiling cooling device locally and strongly captures heat from the heat generating component by the vaporization of the first coolant enclosed in the boiling cooling device thermally connected to the heat generating component. At the same time, the second coolant with the boiling point T₂ higher than the boiling point T₁ of the first coolant completely captures the heat from the boiling cooling device. Hence, the overall electronic device is cooled. In the cooling, the second coolant with a high boiling point effectively and strongly cools the peripheral electronic components mounted on the electronic device. In other words, the cooling medium for secondary cooling (the second coolant) used for boiling cooling the processor, which is a major heat generating source, also functions as a cooling medium for effective primary cooling for the peripheral electronic components. Consequently, cooling performances for the electronic device can be significantly improved. The boiling point of the second coolant T₂ is higher than the boiling point T₁ of the first coolant. Hence, the second coolant is less prone to be evaporated, which may allow the cooling bath containing the second coolant to be an unclosed open space. Thus, this eliminates the necessity of providing a complicated, expensive structure. Moreover, a cooling fan and cooling tubes for forced cooling, which are required in the previously existing boiling cooling system, are all unnecessary, resulting in a decrease in the volume occupied by system components. Accordingly, simplification and downsizing of the cooling system are achieved. Furthermore, in the previously existing boiling cooling system, mechanisms, such as complicated tubes and a large-sized heat sink, are required for cooling the processor, which is a major heat generating source. The presence of these mechanisms inevitably interferes with cooling the peripheral electronic components that have to rely on air cooling. Contrary to such previously existing techniques, according to the present invention, complicated tubes and a large-sized heat sink are eliminated, which is advantageous for cooling the peripheral electronic components. Moreover, the cooling medium for secondary cooling (the second coolant) is distributed throughout the overall board of the electronic device. Thus, the peripheral electronic components can be highly efficiently cooled. Note that, in the present specification, the cooling bath with “the open space” also includes cooling baths with a simple closed structure to the extent that the serviceability of the electronic device is not degraded. For example, a structure in which a top plate is detachably mounted on the opening of a cooling bath through a gasket, for example, can be a simple closed structure.

The object and advantages of the present invention described above and other objects and advantages will be more clearly appreciated through the description of an embodiment below. Of course, the embodiment described below is an example, which does not limit the present invention.

### BRIEF DESCRIPTION OF DRAWINGS

FIG. 1 is an enlarged vertical cross sectional view of the configuration of the main components of a cooling system according to an embodiment of the present invention.

FIG. 2A is a perspective view of an exemplary boiling cooling device.

FIG. 2B is a perspective view of another exemplary boiling cooling device.

FIG. 2C is a perspective view of still another exemplary boiling cooling device

FIG. 3 is a vertical cross sectional view of the configuration of a high-density cooling system according to an embodiment of the present invention.

FIG. 4 is a cross sectional view of the configuration of the high-density cooling system according to an embodiment of the present invention when viewed from the side.

FIG. 5 is a schematic diagram of a cooling system in which a drive system and a cooling system are provided in a distribution path joining the outlet and the inlet of the cooling bath to each other.

### DESCRIPTION OF EMBODIMENTS

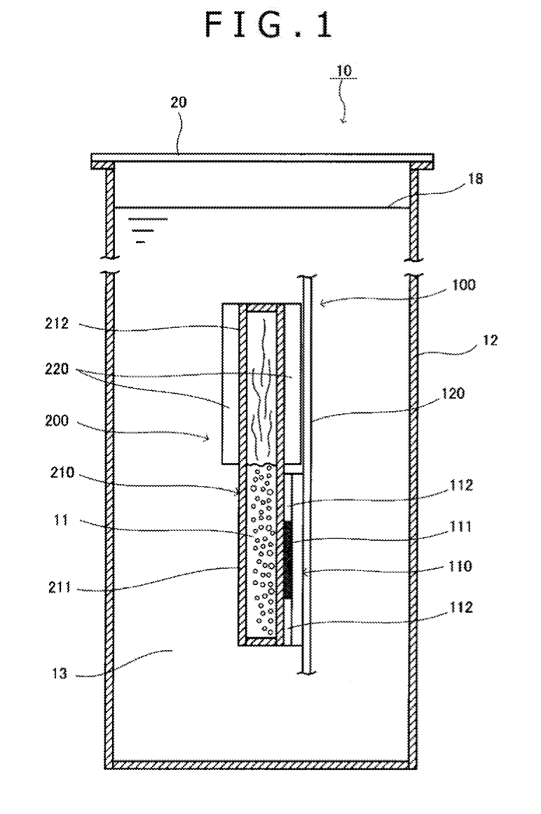

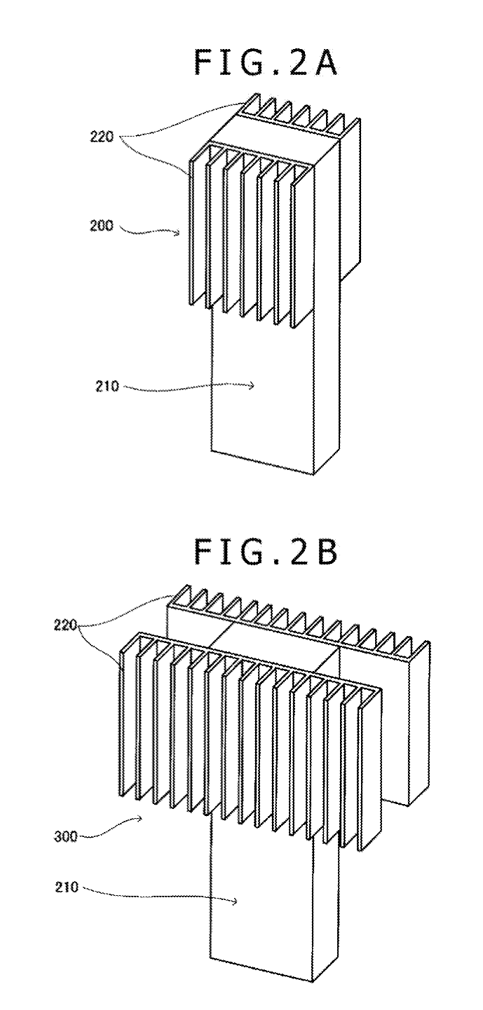

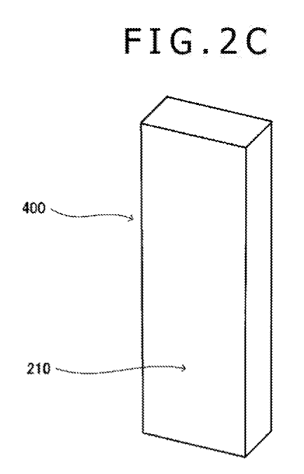

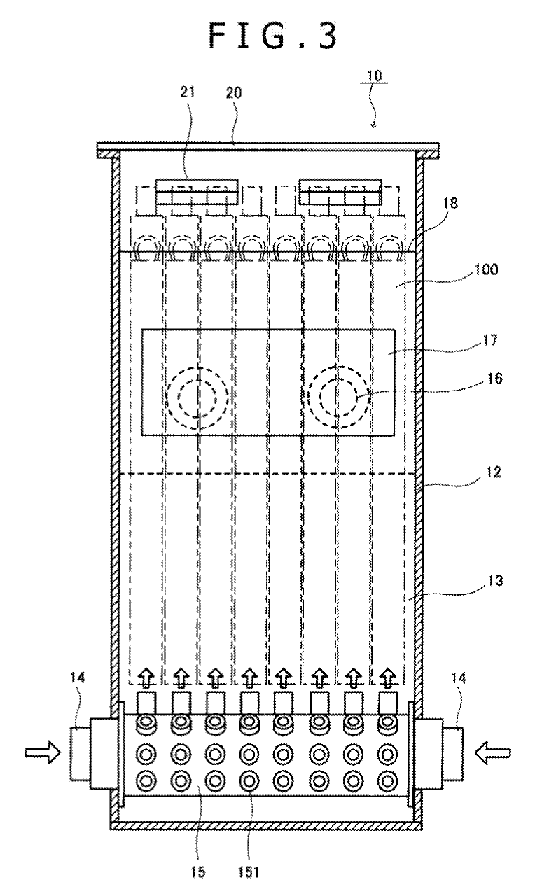

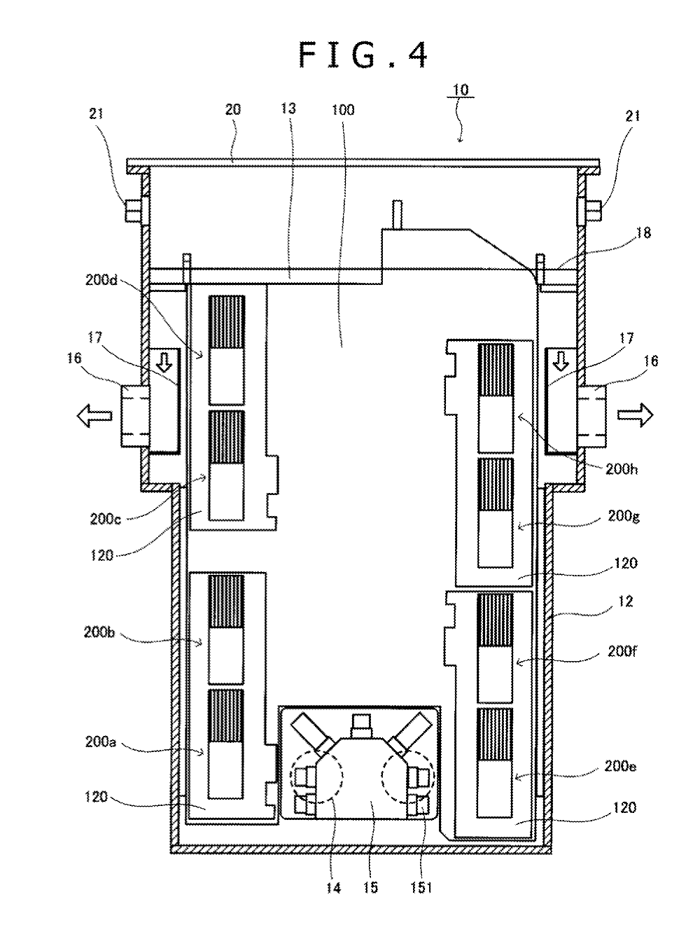

In the following, a preferred embodiment of a cooling system according to the present invention will be described in detail with reference to the drawings. In the description of the embodiment, first, the configuration of the main components of a cooling system will be described with reference to FIGS. 1, 2A, 2B, and 2C. In the system, an electronic device having a processor, which is a heat generating component, mounted on a board is housed in a cooling bath for cooling. The processor includes a die (a semiconductor chip) and a heat spreader surrounding the die. Subsequently, referring to FIGS. 3 and 4, the configuration of a high-density cooling system will be described. As the electronic device, an electronic device in a structure below is provided. Four processor boards each mounted with a plurality of processors are provided. These processor boards are disposed on one face of the electronic device. This makes one unit. Eight units of the electronic devices in total are highly densely housed in a cooling bath for cooling them. Note that, these are only examples. The number of processors per board and a type (a CPU or GPU) of processor can be any numbers and any types. The number of units of electronic devices in the high-density cooling system can also be any numbers. These do not limit the configuration of the electronic device according to the present invention.

Referring to FIG. 1, a cooling system 10 includes a cooling bath 12. In the open space of the cooling bath 12, a second coolant 13 with a boiling point T₂ is contained. In the open space of the cooling bath 12, an electronic device 100 is housed, on which a processor 110 is mounted as a heat generating component on a board 120. The electronic device 100 is immersed in the second coolant 13. The processor 110 includes a die 111 and a heat spreader 112 surrounding the die. Note that, the use of the heat spreader is an option, which may be omitted. Of course, peripheral electronic components other than the processor 110 are mounted on the board 120 of the electronic device 100. However, these electronic components are omitted in FIG. 1. A boiling cooling device 200 is a cooling device thermally connected to the processor 110, which is a heat generating component. The boiling cooling device 200 encloses a first coolant 11 with a boiling point T₁ (where T₂>T₁).

As shown in FIGS. 1 and 2A, the boiling cooling device 200 includes a closed container 210 having a heat receiving part 211 and a heat dissipating part 212, and a heat dissipation member 220 provided on the heat dissipating part 212. In the example shown in FIGS. 1 and 2A, the closed container 210 has a thin box shape formed of six plates. These plates form a space in a rectangular cross section. Note that, the outer and inner structures of the closed container 210 are options. The dimensions and the shape may be appropriately determined taking into account of the area of the heat dissipation surface of an object to be cooled and the quantity of heat to be generated. For convenience, in the embodiment, the lower half of the closed container 210 in a box shape is referred to as the heat receiving part 211, and the upper half is referred to as the heat dissipating part 212. However, as described later, note that only one face of the lower half of the closed container 210 is connected to the heat generating surface of the processor 110. For the material of the closed container 210, metals of excellent thermal conductivity, such as aluminum, copper, and solver, can be used, but the materials are not limited to these metals.

In the closed container 210, the first coolant 11 is enclosed in an amount to the extent that the space of the heat receiving part 211 is filled with the first coolant 11. For the first coolant, a hydrofluoroether (HFE) compound can be preferably used, which is known as Novec 7000 with a boiling point of 34° C., Novec 7100 with a boiling point of 61° C., Novec 7200 with a boiling point of 76° C., and Novec 7300 with a boiling point of 98° C. Novec 700, Novec 7100, Novec 7200, and Novec 7300 are trade names of 3M Company. Novec is the trademark of 3M Company. Hereinafter, the same meaning is applied. However, the material of the first coolant is not limited to these materials. Commonly, it is desirable to manage the operating temperature of the processor at a temperature of 100° C. or less. From this concept, preferably, a coolant with a boiling point of 100° C. or less is used so that the boiling cooling function of the boiling cooling device 200 is not lost. Note that, publicly known methods are applicable to the method of enclosing the first coolant in the closed container 210, and hence the detailed description is omitted here.

On the heat receiving part 211 of the closed container 210, the back face of the closed container 210 in a box shape is thermally connected to the heat generating surface of the processor 110. For the connection, adhesives of excellent thermal conductivity, such as metal grease, can be used. However, materials for the connection are not limited to these adhesives. Note that, in terms of the orientation of the boiling cooling device 200 when the boiling cooling device 200 is connected to the heat generating surface of the processor 110, the boiling cooling device 200 only has to be directed to the heat generating surface so that the heat dissipating part 212 is located above the heat receiving part 211 when the boiling cooling device 200 and the electronic device 100 are immersed in the second coolant 13.

On the heat dissipating part 212 of the closed container 210, a heat dissipation member (heat dissipating fins) 220 is provided both on the front face and the back face of the closed container 210 in a box shape. The heat dissipation member 220 can manage the quantity of heat captured by the second coolant by increasing and decreasing the surface area of the heat dissipating part 212. The material of the heat dissipation member 220 may be a material similar to the material of the closed container 210. For a method of fixing the heat dissipation member 220 to the closed container, a publicly known method, such as brazing, may be used.

FIG. 2B is another example of the boiling cooling device. Components similar to the components of FIG. 2A are designated similar reference numerals and signs. In the example shown in FIG. 2B, in a boiling cooling device 300, the size of the heat dissipation member 220 is increased in the width direction, and the number of fins is increased. Thus, the quantity of heat to be released is increased more than in the boiling cooling device 200 shown in FIG. 2A. Conversely, when desired cooling performances can be obtained because of advanced material technology of the closed container 210 in future without increasing the surface area by additionally providing the heat dissipation member 220, the additional provision of the heat dissipation member 220 may be omitted. In other words, as still another example shown in FIG. 2C, a boiling cooling device 400 may be configured only of a closed container 210 with no heat dissipation member.

Returning to FIG. 1, the cooling bath 12 contains the second coolant 13 to a liquid level 18 in an amount enough to entirely immerse the boiling cooling device 200 and the electronic device 100. For the second coolant, a fluorine inert fluid made of a fully fluorinated compound (a perfluorocarbon compound) can be preferably used, which is known as Fluorinert FC-72 with a boiling point of 56° C., Fluorinert FC-770 with a boiling point of 95° C., Fluorinert FC-3283 with a boiling point of 128° C., Fluorinert FC-40 with a boiling point of 155° C., and Fluorinert FC-43 with a boiling point of 174° C. Fluorinert FC-72, Fluorinert FC-770, Fluorinert FC-3283, Fluorinert FC-40, and Fluorinert FC-43 are trade names of 3M Company. Fluorinert is a trademark of 3M Company. Hereinafter, the same meaning is applied. However, the material of the second coolant is not limited to these materials. The importance is to select a cooling medium with the boiling point T₂ higher than the boiling point T₁ of the first coolant 11 for the second coolant 13 according to the present invention. For an example, in the case in which Novec 7000 with a boiling point of 34° C. is used for the first coolant 11, Fluorinert FC-43 with a boiling point of 174° C. can be preferably used for the second coolant 13.

The inventor focused attention on a fully fluorinated compound because the fully fluorinated compound is a compound of excellent properties, such as high electrical insulation properties, a high heat transfer capacity, being inert, thermally and chemically stable, nonflammable, and free from oxygen, allowing zero ozone depletion potential. The inventor completed the invention of a cooling system using a coolant containing a fully fluorinated compound as a main component for a cooling medium for liquid immersion cooling for electronic devices packed in high density, a patent application of which was filed (Japanese Patent Application Laid-Open Publication No. 2014-170616). As disclosed in the senior application, when Fluorinert FC-43 or FC-40 is specifically used for the second coolant, a plurality of electronic devices disposed in high density in the cooling bath with a small volume can be efficiently cooled with a great decrease in a loss of the second coolant 13 from the cooling bath having an open space due to evaporation, which is significantly advantageous. However, as already described, in the present invention, of course, no limitation is imposed on the selection of any one of Fluorinert FC-72, FC-770, or FC-3283 for a coolant with the boiling point T₂ higher than the boiling point T₁ of the first coolant 11.

Note that, Fluorinert FC-43 or FC-40 has a boiling point of 150° C. or more, which is far less prone to be evaporated. Thus, a top plate 20 provided on the upper opening of the cooling bath 12 only has to be openably supported by a hinge, not shown, provided on one of the edges of the upper opening of the cooling bath 12 for easy access to the electronic device 100 for maintenance. As described later with reference to FIGS. 3 and 4, in the configuration of the cooling bath 12, the cooling bath 12 is provided with inlets and outlets, not shown in FIG. 1, for the second coolant 13. Thus, the electronic device 100 housed in the open space of the cooling bath 12 is immersed in the second coolant 13 distributed in the open space of the cooling bath 12, and the electronic device 100 is directly cooled.

Next, the operation of the cooling system 10 will be described. After the operation of the electronic device 100 is started, when the surface temperature of the processor 110 is increased and reached at a temperature higher than the boiling point of the first coolant 11 (e.g. a temperature of 34° C. in Novec 7000), the first coolant 11 enclosed in the closed container 210 of the boiling cooling device 200 begins to evaporate in bubbles from the surface of the inner wall of the heat receiving part 211 of the closed container 210. The vaporized first coolant 11 goes upwards in the space of the heat dissipating part 212 of the closed container 210. However, the temperature of the second coolant 13 (e.g. Fluorinert FC-43) around the boiling cooling device 200 and the electronic device 100 is kept low at a temperature in a range of 17 to 23° C., for example. Thus, the vaporized first coolant 11 is condensed on the surface of the inner wall of the heat dissipating part 212 of the closed container 210. The first coolant 11 moves on the surface of the inner wall toward the heat receiving part 211 in a liquid phase state, and drops due to gravity. The boiling cooling device 200 locally and strongly captures heat from the processor 110 due to circulation of the cooling medium between the gaseous phase and the liquid phase in the boiling cooling device 200. At the same time, the second coolant 13 around the boiling cooling device 200 completely captures the heat from the boiling cooling device 200 (mainly through the heat dissipation member 220). Thus, the overall electronic device is cooled. In the cooling, the second coolant 13 with a high boiling point effectively and strongly cools peripheral electronic components (not shown) mounted on the board 120 of the electronic device 100. In other words, the cooling medium for secondary cooling (the second coolant 13) used for boiling cooling for the processor 110, which is a major heat generating source, also functions as a cooling medium for effective primary cooling for the peripheral electronic components (not shown). Consequently, cooling performances for the electronic device 100 can be significantly improved.

The boiling point T₂ of the second coolant 13 is higher than the boiling point T₁ of the first coolant 11, and hence the second coolant 13 is less prone to be evaporated, which may allow the cooling bath 12 containing the second coolant 13 to be an unclosed open space. Thus, this eliminates the necessity of providing a complicated, expensive structure. Moreover, a cooling fan and cooling tubes for forced cooling, which are required in the previously existing boiling cooling system, are all unnecessary, resulting in a decrease in the volume occupied by system components. Accordingly, simplification and downsizing of the cooling system are achieved. Furthermore, in the previously existing boiling cooling system, mechanisms, such as complicated tubes and a large-sized heat sink, are required for cooling the processor, which is a major heat generating source. The presence of these mechanisms inevitably interferes with cooling the peripheral electronic components that have to rely on air cooling. Contrary to the previously existing techniques, according to the present invention, complicated tubes and a large-sized heat sink are eliminated, which is advantageous for cooling the peripheral electronic components (not shown). Moreover, the cooling medium for secondary cooling (the second coolant 13) is distributed throughout the board 120 of the electronic device 100. Thus, the peripheral electronic components (not shown) can be cooled highly efficiently.

Next, referring to FIGS. 3 and 4, the configuration of the high-density cooling system will be described. Note that, components similar to the components of the cooling system shown in FIG. 1 are designated similar reference numerals and signs, and the detailed description is omitted. In the configuration of the cooling system 10, two inlets 14 are provided on the left side face of the bottom part and on the right side face of the bottom part the cooling bath 12, and two outlets 16 are provided on the front side and on the back side of the cooling bath 12. In the open space of the cooling bath 12, eight units of the electronic devices 100 in total are housed. The electronic devices 100 are immersed and directly cooled in the second coolant 13 distributed in the open space.

In the example shown in FIGS. 3 and 4, one unit of the electronic device 100 has a structure in which two processors are mounted on a processor board and four processor boards are disposed on one face. Boiling cooling devices 200a, 200b, 200c, 200d, 200e, 200f, 200g, and 200h are thermally connected to the heat generating surfaces of the corresponding processors. As shown in FIG. 4, the boiling cooling devices 200a, 200b, 200c, and 200d are vertically disposed at different locations on the board 120. This is the same as in the boiling cooling devices 200e, 200f, 200g, and 200h.

Note that, as described above, Fluorinert FC-43 or FC-40 that can be preferably used as the second coolant 13 is far less prone to be evaporated. Thus, the liquid level 18 is kept for a long time. Various cables connected to the electronic devices 100 can be led out of the cooling bath 12 with the cables being held on a cable clamp 21.

On the bottom part of the cooling bath 12, a header 15 is disposed extending in the width direction (in the lateral direction) of the cooling bath. One end of the header 15 is joined to two inlets 14 on the left side face of the bottom part of the cooling bath 12. The other end of the header 15 is joined to two inlets 14 on the right side face of the bottom part of the cooling bath 12. On the header, a plurality of nozzles 151 is provided in an array. Thus, in the configuration of the cooling bath 12, the second coolant 13 supplied from the left and right inlets 14 is discharged from the plurality of nozzles 151.

The nozzle 151 is formed of a plurality of nozzle groups provided being spaced at a predetermined gap in the longitudinal direction (the lateral direction) of the header 15. The nozzle groups are configured of the nozzles 151 disposed on the header 15 so that the discharge ports of the nozzles 151 are radially distributed on the surface of the header 15 which has a hexagonal cross section.

On the cooling bath 12 side of two outlets 16 provided each on the front side and on the back side of the cooling bath 12, a region is provided. The region is partitioned by a coolant guide plate 17 that covers the outlets 16 overall except the upper part for forming an opening. Thus, the second coolant 13 flows from the opening located above toward the outlets 16.

Next, referring to FIGS. 3 and 4, advantages of the high-density cooling system according to an embodiment of the present invention achieved by providing the header 15 will be described.

The high-density cooling system is configured in which the second coolant 13 supplied from the inlets 14 is discharged from the plurality of nozzles 151 provided on the header 15 in an array. Thus, the cooled second coolant 13, which is cooled by a heat exchanger, described later, can be distributed through the overall cooling bath 12. Accordingly, the effect of direct cooling by forced convection of the second coolant 13 to the electronic device 100 can be improved.

Moreover, the nozzle groups provided being spaced at a predetermined gap in the longitudinal direction of the header 15 are configured of the nozzles 151 disposed so that the discharge ports are radially distributed. Thus, the cooled second coolant 13 can be more efficiently distributed through the overall cooling bath 12. Specifically, as shown in FIGS. 3 and 4, the plurality of nozzle groups individually corresponds to a plurality of the electronic devices 100. Thus, cooling performances for the electronic devices 100 can be made uniform, even though the electronic devices 100 are housed in the cooling bath 12 in high density.

Even in the case in which the second coolant 13 is distributed as described above, the temperature profile of the second coolant 13 is possibly produced in the cooling bath 12. In other words, a temperature profile is possibly produced in which the temperature is more increased as the second coolant 13 in the cooling bath 12 moves from the bottom part of the cooling bath 12 to the liquid level 18. When such a temperature profile is produced, even though the boiling cooling devices having the same performances are thermally connected to the processors having the same performances, it is likely to vary cooling performances depending on the temperature profile of the second coolant 13 and differences in the locations at which the processors are mounted on the boards. As an exemplary application to deal with such cases, for the boiling cooling devices (e.g. the boiling cooling devices 200c, 200d, 200g, and 200h) located vertically at upper locations on the boards, a coolant with a boiling point higher than the boiling point of a coolant used for the cooling devices (e.g. the boiling cooling devices 200a, 200b, 200e, and 200f) located at lower locations on the boards may be used. Thus, cooling performances can be made more uniform, regardless of the temperature profile of the second coolant and the locations at which the processors are mounted.

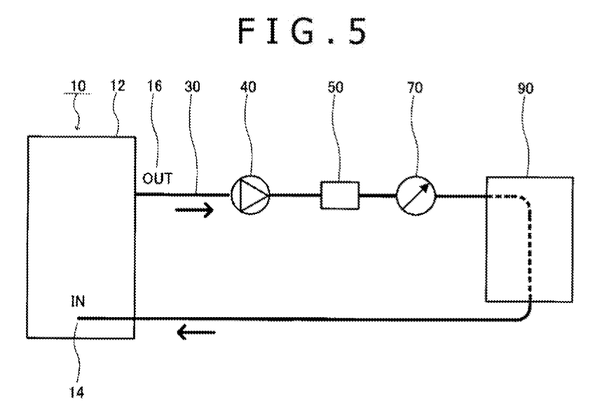

Referring to FIG. 5, an exemplary configuration of a distribution path will be described, in which the second coolant discharged from the outlet of the cooling bath is cooled by the heat exchanger and the cooled second coolant is supplied to the inlet of the cooling bath. As shown in FIG. 5, the outlet 16 and the inlet 14 of the cooling bath 12 are joined to each other through a distribution path 30. In the distribution path 30, a pump 40 that moves the second coolant 13 and a heat exchanger 90 that cools the second coolant 13 are provided. Note that, a flow rate adjustment valve 50 and a flow meter 70 for adjusting the flow rate of the second coolant 13 carried though the distribution path 30 are also provided in the distribution path 30.

The pump 40 preferably includes a function to move a liquid with a relatively large kinematic viscosity (a kinematic viscosity of more than 3 cSt at an ambient temperature of 25° C.). This is because in the case in which Fluorinert FC-43 or FC-40 is used for the second coolant 13, for example, the kinematic viscosity of FC-43 is in a range of about 2.5 to 2.8 cSt, and the kinematic viscosity of FC-40 is in a range of about 1.8 to 2.2 cSt. The flow rate adjustment valve 50 only has to be a valve that is manually operated. Additionally, the flow rate adjustment valve 50 only has to be a valve that includes an adjustment mechanism for constantly keeping a flow rate based on the measurement value of the flow meter 70. Moreover, the heat exchanger 90 only has to be various circulation type heat exchangers (radiators or chillers) or coolers.

In the embodiment, an example is shown in which the processor 110 is mounted on the board of the electronic device 100. The processor may include a CPU, a GPU, or a CPU and a GPU. The processor may include a high speed storage, a chip set, a network unit, a PCI Express bus, a bus switch unit, an SSD, and a power unit, not shown. The electronic device 100 may be an electronic device, such as a storage device like a server including a blade server, a router, and an SSD.

In the embodiment, for the closed container 210 of the boiling cooling device 200, an example of a container in a tall, thin box shape is shown. This container may be used in such a manner that the container is placed as a horizontally-long box. The heat receiving part and the heat dissipating part of the closed container 210 are separately described on the upper half and the lower half of the closed container 210 in a tall box shape, for convenience. The heat receiving part and the heat dissipating part may be combined together vertically. In this case, the face thermally connected to the heat generating surface of the processor 110 is the heat receiving part.

As described above, in short, the cooling system according to the present invention has special advantages below in comparison with the previously existing techniques. First, in comparison with a simple boiling cooling system, conventionally, peripheral electronic components other than a processor are cooled by air cooling. However, in the present invention, peripheral electronic components can also be effectively and strongly cooled by a cooling medium with a high boiling point, other than a processor, which is a major component or a component that have to be cooled because of the largest heating value. In other words, the cooling medium for secondary cooling (the second coolant) used for boiling cooling for the processor, which is a major heat generating source, also functions as a cooling medium for effective primary cooling for the other peripheral electronic components. Thus, cooling performances for the electronic device can be significantly improved. Moreover, in the previously existing boiling cooling systems, mechanisms, such as complicated tubes and a large-sized heat sink, are required for cooling the processor, which is a major heat generating source. The presence of these mechanisms inevitably interferes with cooling the peripheral electronic components that have to rely on air cooling. In contrast to this, according to the present invention, complicated tubes and a large-sized heat sink are eliminated, which is advantageous for cooling the peripheral electronic components. Furthermore, the cooling medium for secondary cooling (the second coolant) is distributed throughout the overall board of the electronic device. Thus, the peripheral electronic components can be highly efficiently cooled.

Lastly, the following describes further advantages achieved from a preferred embodiment of the present invention.

In a preferred embodiment of the present invention, when the boiling point of the second coolant is a temperature of 150° C. or more, the second coolant is less prone to be evaporated. Thus, a loss of the second coolant due to evaporation can be greatly decreased as well as a possibility of locally boiling the second coolant in the cooling bath can be avoided, even in the case in which the cooling bath is an unclosed open space. The cooling system using a previously existing fluorocarbon compound has problems below. However, in the case of using a fully fluorinated compound with a boiling point of 150° C. or more for the second coolant, all of these problems can be solved.
(1) There is a risk that in boiling a fluorocarbon compound, a trace amount of hydrogen or oxygen present around the fluorocarbon compound is captured to generate fluorine compounds, such as extremely toxic hydrogen fluorides.
(2) There is a possibility that even in an inert fluid, some electronic components, which are operating at extremely high speed, locally reach high temperatures, resulting in boiling a fluorocarbon compound.
(3) There is a possibility that when the cooling system fails and causes a problem, which results in a loss of cooling functions or degraded cooling functions, a fluorocarbon compound boils due to an increase in the temperature of the coolant above the design limits of the cooling system.
(4) There is a possibility that in the case in which electronic components or components of a chassis are dropped in the cooling bath or external foreign substances are trapped in the cooling bath, which is an open system, liquid circulation locally stops moving in the cooling bath to locally increase temperature, resulting in boiling the fluorocarbon compound.

In a preferred embodiment of the present invention, the electronic device has a plurality of heat generating components vertically disposed at different locations on the board, and the boiling cooling devices are thermally connected to the plurality of individual heat generating components. A coolant with a boiling point higher than the boiling point of a coolant used for the cooling device located at a lower location on the board is used for the cooling device located vertically at an upper location on the board when the cooling devices are immersed in the second coolant. In this case, cooling performances can be made more uniform, regardless of the temperature profile of the second coolant and the locations at which the heat generating components are disposed.

In a preferred embodiment of the present invention, the cooling bath includes an inlet and an outlet for the second coolant. The outlet and the inlet are joined to each other through a distribution path provided on the outside of the cooling bath. In the distribution path, at least one pump that moves the second coolant and a heat exchanger that cools the second coolant are provided. In this case, a distribution path is configured in which the second coolant discharged from the outlet of the cooling bath is cooled by the heat exchanger and the cooled second coolant is supplied to the inlet of the cooling bath. Thus, with the distribution path, the electronic device can be continuously and stably operated.

In a preferred embodiment of the present invention, a header joined to the inlets and extending in the width direction of the cooling bath is disposed on the bottom part of the cooling bath. The second coolant supplied from the inlets is discharged from a plurality of nozzles provided in an array on the header. With this configuration, the cooled second coolant can be distributed through the overall cooling bath, and hence the effect of direct cooling by forced convection can be improved.

In a preferred embodiment of the present invention, a plurality of nozzles is formed of a plurality of nozzle groups provided being spaced at a predetermined gap in the longitudinal direction of the header. The nozzle groups are configured of nozzles disposed so that discharge ports are radially distributed. With this configuration, the cooled second coolant can be further efficiently distributed through the overall cooling bath, and hence the effect of direct cooling by forced convection can be further improved.

In a preferred embodiment of the present invention, in the case in which the plurality of nozzle groups individually corresponds to a plurality of electronic devices, cooling performances for the electronic device can be made uniform when the electronic devices are housed in the cooling bath in high density.

### INDUSTRIAL APPLICABILITY

The present invention is widely applicable to cooling systems that efficiently cool electronic devices.

### LIST OF REFERENCE SIGNS

10 Cooling system
100 Electronic device
110 Processor
111 Die (chip)
112 Heat spreader
120 Board
200, 200a to 200h, 300, 400 Boiling cooling device
210 Closed container
211 Heat receiving part
212 Heat dissipating part
220 Heat dissipation member (heat dissipating fins)
11 First coolant
12 Cooling bath
13 Second coolant
14 Inlet
15 Header
151 Nozzle
16 Outlet
17 Coolant guide plate
18 Liquid level
20 Top plate
21 Cable clamp
30 Distribution path
40 Pump
50 Flow rate adjustment valve
70 Flow meter
90 Heat exchanger

1. A cooling system that immerses an electronic device in a coolant for directly cooling the electronic device, the system comprising:
a boiling cooling device thermally connected to at least one heat generating component of an electronic device, the boiling cooling device enclosing a first coolant with a boiling point T₁, and
a cooling bath containing a second coolant with a boiling point T₂ higher than the boiling point T₁ of the first coolant, the boiling cooling device and the electronic device being immersed in the second coolant and directly cooled in the cooling bath.

2. The cooling system according to claim 1,
wherein: the boiling cooling device includes
a closed container having a heat receiving part and a heat dissipating part and
a heat dissipation member provided on the heat dissipating part, and
when the boiling cooling device and the electronic device are immersed in the second coolant, the boiling cooling device is thermally connected to the heat generating component so that the heat dissipating part is located above the heat receiving part.

3. The cooling system according to claim 1,
wherein: the boiling point of the first coolant is a temperature of 100° C. or less, and
the boiling point of the second coolant is a temperature of 150° C. or more.

4. The cooling system according to claim 3,
wherein the first coolant contains a fluorocarbon compound as a main component.

5. The cooling system according to claim 3,
wherein the second coolant contains a fully fluorinated compound as a main component.

6. The cooling system according to claim 1,
wherein: the electronic device has a plurality of heat generating components vertically disposed at different locations on a board;
the boiling cooling device is thermally connected to the plurality of heat generating components individually, and
a coolant with a boiling point higher than a boiling point of a coolant used for a cooling device located at a lower location on the board is used for a cooling device located vertically at an upper location on the board when the cooling devices are immersed in the second coolant.

7. The cooling system according to claim 1,
wherein: the cooling bath includes an inlet and an outlet for the second coolant,
the outlet is joined to the inlet through a distribution path externally provided on the cooling bath, and
in the distribution path, at least one pump that moves the second coolant and a heat exchanger that cools the second coolant are provided.

8. The cooling system according to claim 7,
wherein: the system is configured in which a header joined to the inlet and extending in a width direction of the cooling bath is disposed on a bottom part of the cooling bath so that the second coolant supplied from the inlet is discharged from a plurality of nozzles provided in an array on the header.

9. The cooling system according to claim 8,
wherein: the plurality of nozzles is formed of a plurality of nozzle groups provided being spaced at a predetermined gap in a longitudinal direction of the header, and
the nozzle groups are configured of nozzles disposed so that discharge ports are radially distributed.

10. The cooling system according to claim 8,
wherein the plurality of nozzle groups individually corresponds to a plurality of the electronic devices immersed in the second coolant.

11. A cooling method for an electronic device comprising:
thermally connecting a boiling cooling device enclosing a first coolant to at least one heat generating component of an electronic device, and
immersing the boiling cooling device and the electronic device in a second coolant with a boiling point T₂ higher than a boiling point T₁ of the first coolant.

12. The method according to claim 11,
wherein: the boiling cooling device includes
a closed container having a heat receiving part and a heat dissipating part and
a heat dissipation member provided on the heat dissipating part, and
when the boiling cooling device and the electronic device are immersed in the second coolant, the boiling cooling device is thermally connected to the heat generating component so that the heat dissipating part is located above the heat receiving part.

13. The method according to claim 11,
wherein: the boiling point of the first coolant is a temperature of 100° C. or less; and
the boiling point of the second coolant is a temperature of 150° C. or more.

14. The method according to claim 13,
wherein the first coolant contains a fluorocarbon compound as a main component.

15. The method according to claim 13,
wherein the second coolant contains a fully fluorinated compound as a main component.
